(19) United States
(12) Patent Application Publication
(10) Pub. No.: US 2020/0283886 A1
(43) Pub. Date: Sep. 10, 2020

(54) Method For Manufacturing A Humidity Sensor And Humidity Sensor

(71) Applicant: MEAS France, Toulouse (FR)

(72) Inventor: Emilien Durupt, Francarville (FR)

(73) Assignee: MEAS France, Toulouse (FR)

(21) Appl. No.: 16/881,586

(22) Filed: May 22, 2020

Related U.S. Application Data
(63) Continuation of application No. PCT/EP2018/083470, filed on Dec. 4, 2018.

(30) Foreign Application Priority Data
Dec. 8, 2017 (EP) 17306733.1

(51) Int. Cl. C23C 14/22; G01N 27/22; C25D 11/18

(52) U.S. Cl. CPC C23C 14/225; C25D 11/18; G01N 27/225

(57) ABSTRACT

A method of manufacturing a relative humidity sensor includes the steps of providing a substrate, providing a first electrode and an electrical connection element on or over the substrate, providing an insulating layer to electrically isolate the first electrode from the electrical connection element, providing an inorganic porous dielectric layer over the first electrode or the insulating layer in an area of the first electrode, and depositing a second electrode in or over the inorganic porous dielectric layer by grazing incidence deposition. The second electrode is porous and is electrically connected to the electrical connection element.

### CROSS-REFERENCE TO RELATED APPLICATIONS

This application is a continuation of PCT International Application No. PCT/EP2018/083470, filed on Dec. 4, 2018, which claims priority under 35 U.S.C. § 119 to European Patent Application No. 17306733.1, filed on Dec. 8, 2017.

### FIELD OF THE INVENTION

The present invention relates to a humidity sensor and, more particularly, to a method for manufacturing a humidity sensor.

### BACKGROUND

Relative humidity sensors are known in the art. U.S. Pat. No. 4,651,121 discloses a moisture sensor comprising a substrate, a bottom electrode over the substrate, and an organic moisture sensitive film sandwiched between the bottom electrode and an upper electrode. The capacitance of the sensor changes when water vapor enters the moisture sensitive film. This effect is used to determine variations in the amount of water vapor in the atmosphere by detecting the corresponding changes of the capacitance. Organic material based relative humidity sensors are intrinsically prone to degrading because of chemical ageing of the material and are heat sensitive, amongst other issues due to a low glass temperature transition.

U.S. Pat. No. 8,783,101 B2 discloses another relative humidity sensor based on a nano-structured aluminum oxide thin film. It comprises an anodic aluminum oxide thin film formed from an aluminum substrate which also serves as one electrode. A porous metal layer is formed over the anodic aluminum oxide thin film as a second electrode. This sensor is obtained by stamping an aluminum sheet and anodizing it to form the porous aluminum oxide, then the porous metal layer is formed over the aluminum oxide by sputtering. Using solderable electrode pins connected to the electrodes using spring contacts or conductive glue, the obtained sensor can be plugged or soldered into a circuit. The fabrication method disclosed can, however, not be implemented into high yield microfabrication means which would allow removal of all mechanical assembly steps and reduction of the part to part difference. The parts assembly is tedious and can lead to a lack of alignment precision. Furthermore, an unwanted delamination of the parts can be observed.

### SUMMARY

A method of manufacturing a relative humidity sensor includes the steps of providing a substrate, providing a first electrode and an electrical connection element on or over the substrate, providing an insulating layer to electrically isolate the first electrode from the electrical connection element, providing an inorganic porous dielectric layer over the first electrode or the insulating layer in an area of the first electrode, and depositing a second electrode in or over the inorganic porous dielectric layer by grazing incidence deposition. The second electrode is porous and is electrically connected to the electrical connection element.

### BRIEF DESCRIPTION OF THE DRAWINGS

The invention will now be described by way of example with reference to the accompanying Figures, of which:

FIG. 1A is a side view of a substrate;

FIG. 1B is a side view of a conductive layer on the substrate of FIG. 1A;

FIG. 1C is a side view of an insulating layer on the conductive layer of FIG. 1B;

FIG. 1D is a side view of an aluminum layer on the insulating layer of FIG. 1C;

FIG. 1E is a side view of the aluminum layer of FIG. 1D transformed into a porous dielectric alumina layer;

FIG. 1F is a side view of a relative humidity sensor according to an embodiment;

FIG. 2A is a side view of an electrical drain in the insulating layer of FIG. 1D;

FIG. 2B is a side view of the aluminum layer of FIG. 1D deposited onto the conductive layer;

FIG. 3 is a top view of the porous dielectric alumina layer; and

FIG. 4 is a schematic diagram of deposition of a second electrode on the porous dielectric alumina layer by grazing incidence deposition.

### DETAILED DESCRIPTION OF THE EMBODIMENT(S)

Exemplary embodiments of the present disclosure will be described hereinafter in detail with reference to the attached drawings, wherein like reference numerals refer to like elements. The described embodiments are merely possible configurations and it must be borne in mind that the individual features as described herein can be provided independently of one another or can be omitted altogether while implementing this invention.

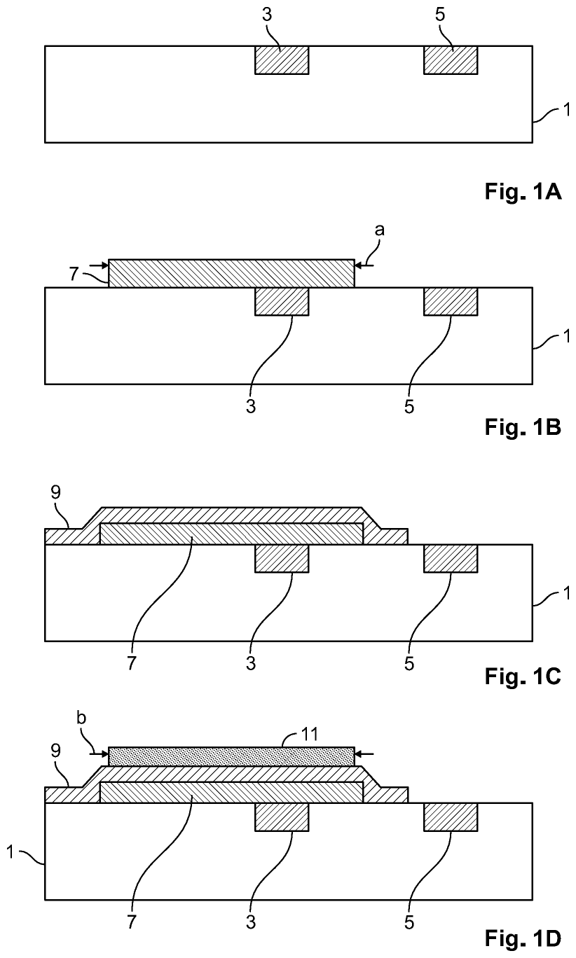

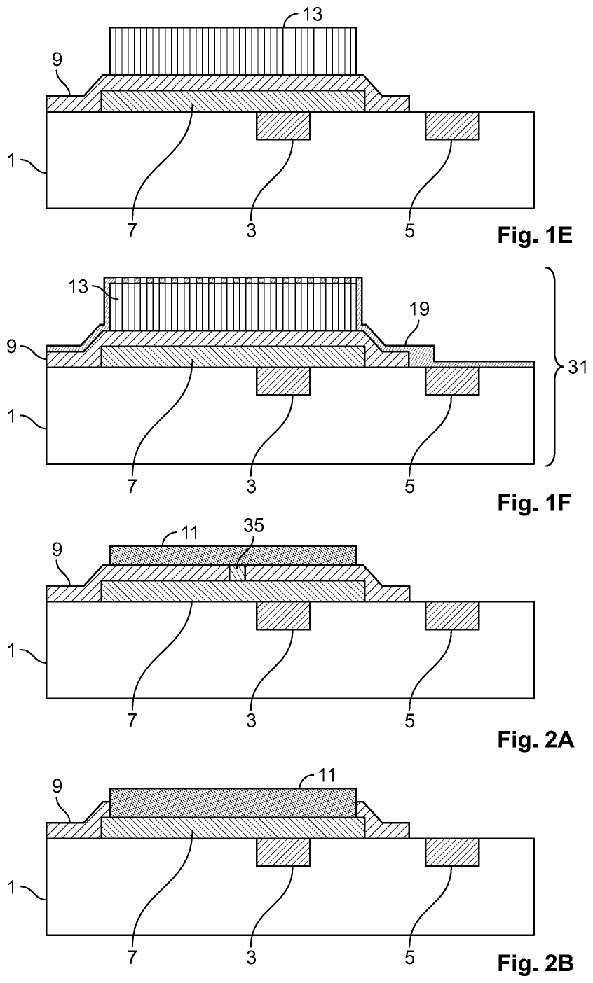

FIGS. 1A-1F illustrate a method of manufacturing a relative humidity sensor according to the invention. It illustrates the formation of one relative humidity sensor, it is, however, to be understood that the described process is a micro fabrication process allowing the simultaneous formation of a plurality of sensor structures.

FIG. 1A shows a substrate 1. In the following process steps the various layers necessary to build the relative humidity sensor will be formed. The substrate 1 has already been processed using layer deposition and patterning steps, so that a first electrode 3 and an electrical connection element 5 are present in or on the surface of the substrate 1. The substrate 1 is a passive substrate. The substrate 1 can be a silicon substrate, a sapphire substrate or any other substrate used in microfabrication production lines. As an alternative an application-specific integrated circuit (ASIC) could also be used as a starting material of the process according to the invention. The first electrode 3 and the electrical connection element 5 are metallic, e.g. from Al, Cu, Au or from any other suitable material.

FIG. 1B illustrates the result of a further layer deposition and patterning step to obtain a conductive layer 7 on the first electrode 3. In an embodiment, the conductive layer 7 is made of a same material as the first electrode 3. The conductive layer 7 has a thickness in a range of 10 to 500 nm. The conductive layer 7 has a lateral extension in a range of 10 μm to 800 μm at least in one dimension.

FIG. 1C illustrates the result of an insulating layer deposition and patterning step. An insulating layer 9 laterally extends over the conductive layer 7 and the first electrode 3 but does not cover the electrical connection element 5. The insulating layer 9 can be SiO₂ layer or made from any other suitable insulating material. In an embodiment, the insulating layer 9 has a thickness in a range of 1 nm to 500 nm.

FIG. 1D illustrates the result of an aluminum deposition and patterning step. An aluminum layer 11 which will be transformed in a dielectric layer in the following process step, has a thickness of 1 nm to 1000 nm and essentially has a lateral extension b corresponding to the lateral extension a of the conductive layer 7.

FIG. 1E illustrates the result of an electrolytic growth step transforming the aluminum layer 11 into a porous dielectric layer 13. The porous dielectric layer 13 is formed of an inorganic material and, in the shown embodiment, is a porous dielectric alumina layer 13. The electrolytic growth is realized in an acidic medium, e.g. oxalic acid and is electrically driven. It turns the aluminum layer 11 into the porous dielectric alumina layer 13. The dielectric alumina layer 13 has a thickness of 1 μm to 5 μm and has essentially a same lateral extension as the conductive layer 7. The growth conditions are controlled such that the entire aluminum layer 11 is transformed into alumina. The alumina can be grown using high yield manufacturing methods.

FIG. 2A illustrates a first variant of the inventive process with additional process steps introduced between the processes illustrated by FIGS. 1D and 1E. Prior to depositing the aluminum layer 11, one or more via holes are etched into the insulating layer 9 in the area over the conductive layer 7 and filled with a conductive material, e.g. aluminum, to provide an electrical drain 35 in the insulating layer 9. The drain 35 allows using the first electrode 3 as a current drain during the electrolytic growth, in particular when, on a wafer scale, the first electrodes 3 are all electrically interconnected.

FIG. 2B illustrates a second variant of the inventive process. Instead of depositing the aluminum layer 11 onto the insulating layer 9 as illustrated in FIG. 1D, it is directly deposited onto conductive layer 7 on the bottom electrode 3. To do so, the patterning step associated with the step illustrated in FIG. 1C is realized such that the surface of the conductive layer 7 becomes at least partially free so that the aluminum layer 11 can then be deposited onto layer 9. Also in this case, the bottom electrodes 3 are interconnected at the wafer scale and current drain during the electrolytic growth can be provided.

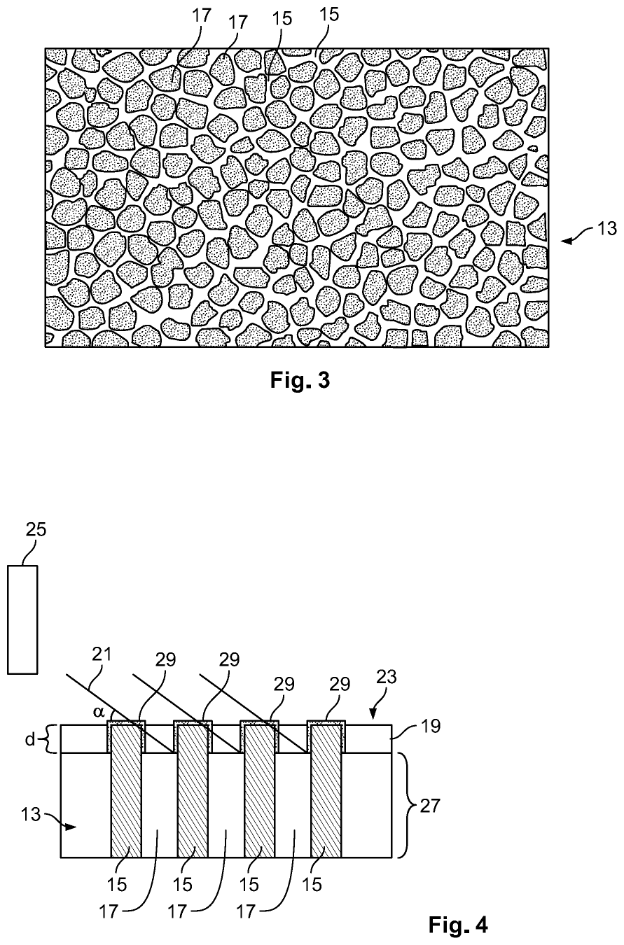

FIG. 3 shows a top view onto the porous dielectric layer 13. A channel matrix in the porous dielectric layer 13 is formed by alumina walls 15 and voids 17. Depending on the growth conditions, a porosity of 5% to 99% of the porous dielectric layer 13 can be achieved. The porous dielectric layer 13 can have a thickness of 200 nm to 10 μm. In other embodiments, the porous dielectric layer 13 can be formed of materials other than alumina, such as another insulating porous inorganic material.

FIG. 1F illustrates the result of a deposition step to form a second electrode 19 over the porous dielectric alumina layer 13. The second electrode 19 is in electric contact with the electrical connection element 5. This can be achieved in the same process step or by an additional layer deposition and patterning step. In this embodiment, the second electrode 19 layer is a gold layer, but any other suitable conductor could be used in variants. The second electrode 19 has a typical thickness in a range of 0.2 nm to 30 nm.

Afterwards, the substrate 1 is diced and individual sensors are packaged. When using interconnected first electrodes 3 as current drain, like explained above with respect to FIGS. 2A and 2B, the dicing will isolate the first electrodes 3 from each other.

FIG. 1F illustrates the structure of the relative humidity sensor 31 according to the invention. The function of the sensor 31 will now be described in greater detail. Humidity in a gas or fluid can enter the porous channel matrix, changing the dielectric properties of the porous alumina layer 13. This change in turn can be sensed by a change in a capacitance of the capacitor formed by the conductive layer 7, the porous alumina layer 13, and the second electrode 19. Via the first electrode 3 and the electrical connection element 5, the corresponding signals can be output to a control circuit of the sensor 31.

In constructing the sensor 31, it is possible to take advantage of microfabrication process steps, leading to high yields and reliability. Using microfabrication, the assembly of the various parts is simplified and alignment can be achieved within the tight limits of microfabrication in contrast to a mechanical assembly. The use of an inorganic humidity sensitive layer, and the absence of organic material, provides long term stability and an extended temperature range in which the sensor 31 functions. Indeed, the sensor 31 can work for temperatures even exceeding 300° C. Due to the use of micro fabrication process steps it is furthermore possible to mass produce the sensor 31 with high yield and reliability. The sensor 31 can be used to detect humidity in gas and/or water in oil or other fluids.

In an embodiment, a plurality of relative humidity sensors 31 can be formed on the same bottom substrate 1 and the first electrodes 3 are then provided such that they are electrically connected to each other. This feature simplifies the set-up to realize the electrolytic growth.

FIG. 4 illustrates schematically the deposition process of the step illustrated in FIG. 1F. The deposition method used according to the invention is a grazing incidence deposition based on a vapor deposition method, such as a metal vapor grazing incidence deposition. In other embodiments, the vapor deposition technique can be sputtering, e-beam evaporation, or any other suitable deposition method.

In this method, as shown in FIG. 4, the flow of evaporated atoms 21, e.g. gold atoms, does not impinge perpendicular to the surface like in standard deposition methods but arrives on the surface of the porous dielectric alumina layer 13 at an angle α that, in various embodiments, is less than 45°, or is less than 30°, with respect to the surface 23 of the porous dielectric alumina layer 13 and taking into account the divergence of the beam. This can be achieved by providing the evaporation target 25 on the side of the substrate 1 instead of opposite to the substrate 1 like in conventional evaporation processes. In addition, the substrate 1 can be rotated around its normal axis during grazing incidence deposition to ensure the homogeneity of the deposited layer with respect to the substrate 1 orientation.

The deposition under an angle smaller than 45°, in particular less than 30°, also has the advantage that the penetration depth d shown in FIG. 4 can be kept small due to the shading effect of the neighboring alumina walls 15 leading to a shaded area 27 without deposited atoms. The penetration depth d scales according to the equation:

d∝Φ tan α

For each one of the pores, a length Φ is a pore diameter of the porous network, and α is an angle between the gold beam and the surface of the porous layer 13. The lower the deposition angle, the less atoms will be deposited inside the porous layer 13 and the lower the penetration depth d, thereby improving the electric properties of the sensor 31.

As shown in FIG. 4, the second electrode 19 in this embodiment is porous like the underlying porous layer 13 with the alumina walls 15 and voids 17, which allows the moisture to enter the porous layer 13. The areas 29 with deposited atoms form the second electrode 19.

In the above description, the terms deposition step and patterning relate to standard fabrication steps used in the semiconductor manufacturing. As an example, the deposition step can relate to chemical vapor deposition (CVD) or physical vapor deposition (PVD), and the patterning step can relate to a lithography imaging and dry or wet etching step.

Modifications to embodiments of the invention described in the foregoing are possible without departing from the scope of the invention as defined by the accompanying claims. Expressions such as “including”, “comprising”, “incorporating”, “consisting of”, “have”, “is” used to describe and claim the present invention are intended to be construed in a non-exclusive manner, namely allowing for items, components or elements not explicitly described also to be present. Reference to the singular is also to be construed to relate to the plural.

What is claimed is:

1. A method of manufacturing a relative humidity sensor, comprising the steps of:
providing a substrate;
providing a first electrode and an electrical connection element on or over the substrate;
providing an insulating layer to electrically isolate the first electrode from the electrical connection element;
providing an inorganic porous dielectric layer over the first electrode or the insulating layer in an area of the first electrode; and
depositing a second electrode in or over the inorganic porous dielectric layer by grazing incidence deposition, the second electrode is porous and is electrically connected to the electrical connection element.

2. The method of claim 1, wherein the inorganic porous dielectric layer includes alumina.

3. The method of claim 1, wherein providing the inorganic porous dielectric layer includes depositing an aluminum layer and growing a porous alumina layer as the inorganic porous dielectric layer.

4. The method of claim 3, wherein the porous alumina layer is grown by electrolytic growth.

5. The method of claim 3, wherein the insulating layer has an electrical drain electrically connecting the aluminum layer with the first electrode.

6. The method of claim 1, wherein a plurality of relative humidity sensors are formed on the substrate.

7. The method of claim 6, wherein the first electrodes of the relative humidity sensors are electrically connected to each other.

8. The method of claim 1, wherein the inorganic porous dielectric layer has a porosity in a range of 5% to 99%.

9. The method of claim 1, wherein depositing the second electrode includes depositing a conductive layer by grazing incidence deposition.

10. The method of claim 9, wherein the grazing incidence deposition is a metal vapor grazing incidence deposition.

11. The method of claim 1, wherein an angle of an evaporated material flow in the grazing incidence deposition with respect to a surface of the inorganic porous dielectric layer is less than 45°.

12. The method of claim 11, wherein the angle is less than 30°.

13. The method of claim 1, wherein the substrate is a passive substrate.

14. The method of claim 13, wherein the substrate is a silicon substrate, a sapphire substrate, or an application-specific integrated circuit substrate.

15. The method of claim 1, further comprising providing a conductive layer on the first electrode prior to providing the insulating layer.

16. The method of claim 1, wherein the inorganic porous dielectric layer has a thickness in a range between 1 μm to 5 μm and a lateral extension is in a range between 10 μm to 800 μm at least in one dimension.

17. A relative humidity sensor, comprising:
a substrate;
a first electrode on or over the substrate;
an electrical connection element on or over the substrate;
an insulating layer electrically isolating the first electrode from the electrical connection element;
an inorganic porous dielectric layer over the first electrode and/or over the insulating layer; and
a second electrode electrically connected to the electrical connection element and disposed in or over the inorganic porous dielectric layer, the second electrode is porous.

18. The relative humidity sensor of claim 17, wherein the insulating layer does not cover the electrical connection element.

19. The relative humidity sensor of claim 17, wherein the inorganic porous dielectric layer is alumina with a porosity of 5% to 99% and a thickness of 1 μm to 5 μm.

20. The relative humidity sensor of claim 17, wherein the second electrode is a gold layer.
